(19) United States
(12) Patent Application Publication
(10) Pub. No.: US 2015/0092175 A1
(43) Pub. Date: Apr. 2, 2015

(54) LITHOGRAPHY APPARATUS, METHOD OF MEASURING SURFACE POSITION, AND METHOD OF PRODUCING DEVICE

(71) Applicant: CANON KABUSHIKI KAISHA, Tokyo (JP)

(72) Inventor: Shinji Ohishi, Oyama-shi (JP)

(21) Appl. No.: 14/493,861

(22) Filed: Sep. 23, 2014

(30) Foreign Application Priority Data
Sep. 27, 2013 (JP) 2013-201377

(51) Int. Cl. G01B 7/00; G03F 7/20; G01B 7/06

(52) U.S. Cl. CPC G01B 7/003; G01B 7/08; G03F 7/70775
USPC 355/72; 324/658; 355/77

(57) ABSTRACT

An apparatus includes a conductive holding part configured to hold an insulating material, and a capacitance sensor configured to generate an electric field between the capacitance sensor and the holding part. The apparatus determines a surface position of a surface of the insulating material based on information of an output value of the capacitance sensor obtained in a case where the insulating material is located in the electric field and information associated with capacitance of the insulating material, and then adjusts the surface position of the insulating material at a pattern formation position.

### BACKGROUND OF THE INVENTION

1. Field of the Invention

The present invention relates to a lithography apparatus, a method of measuring a surface position, and a method of producing a device.

2. Description of the Related Art

In recent years, an increase in integration density of LSIs has been achieved, and accordingly, a reduction in minimum feature size of circuit patterns of semiconductor devices has been achieved, and there is still a need for a further reduction. To transfer a fine circuit pattern to a target exposure area of a substrate, a vertical position is adjusted such that the target exposure area is within an allowable range corresponding to a depth of focus of an optical system. To achieve this requirement, it is necessary to precisely detect a distance in a direction of an optical axis from the optical system to the surface of the target exposure area of the substrate.

In a lithography apparatus according to a related technique, a surface position is measured using an optical detection system. Japanese Patent Laid-Open No. 2001-143991 discloses a technique of measuring a surface position by using a capacitance sensor as a main surface position measurement device. In this technique, there is a possibility that a measured value by the capacitance sensor is influenced by an insulating material such as an insulating layer, a resist, and the like formed on a substrate, and thus it is necessary to take into account such an influence. To handle such a situation, Japanese Patent Laid-Open No. 2001-143991 also discloses a technique of using an oblique incidence optical detection system together with the above-described capacitance sensor.

However, to install an oblique incidence optical detection system, an enough installation space is applied between the optical system and the surface of the substrate and/or around the optical system. Furthermore, in a case where an extreme ultraviolet (EUV) exposure apparatus or an electron beam lithography exposure apparatus is used as the exposure apparatus, exposure is performed in a vacuum environment, and thus a proper material for the optical detection system so as to achieve high vacuum is selected. Additionally, a cooling apparatus is provided, which may result in an increase in cost.

### SUMMARY OF THE INVENTION

The present invention provides an apparatus for determining a surface position of an insulating material using a capacitance sensor without using together an oblique incidence optical detection system.

According to an embodiment, an apparatus includes a holding part being conductive and configured to hold an insulating material, and a capacitance sensor configured to generate an electric field between the capacitance sensor and the holding part, wherein the lithography apparatus is configured to determine a surface position of a surface of the insulating material based on information of an output value of the capacitance sensor obtained in a case where the insulating material is located in the electric field and information associated with capacitance of the insulating material, and then adjust the surface position of the insulating material at a pattern formation position.

Further features of the present invention will become apparent from the following description of exemplary embodiments with reference to the attached drawings.

### BRIEF DESCRIPTION OF THE DRAWINGS

FIG. 1 is a diagram illustrating a configuration of an exposure apparatus according to a first embodiment.

FIGS. 2A to 2E are diagrams illustrating a sequence of steps of forming a circuit pattern.

FIGS. 3A and 3B are diagrams illustrating a principle of a capacitance sensor.

FIGS. 4A and 4B are diagrams illustrating a manner of performing measurement with a capacitance sensor.

FIG. 5 is a diagram illustrating a manner in which a surface position of a circuit pattern is measured.

FIG. 6 is a diagram illustrating an initial state according to the first embodiment.

FIG. 7 is a diagram illustrating a state in which a fixing part is used according to the first embodiment.

FIG. 8 is a diagram illustrating a state in which a substrate is inserted according to the first embodiment.

FIG. 9 is a diagram illustrating a state in which an insulating layer is formed on the substrate according to the first embodiment.

FIG. 10 is a flow chart illustrating a method of measuring a surface position according to the first embodiment.

FIG. 11 is a diagram illustrating a configuration of an exposure apparatus according to a second embodiment.

### DESCRIPTION OF THE EMBODIMENTS

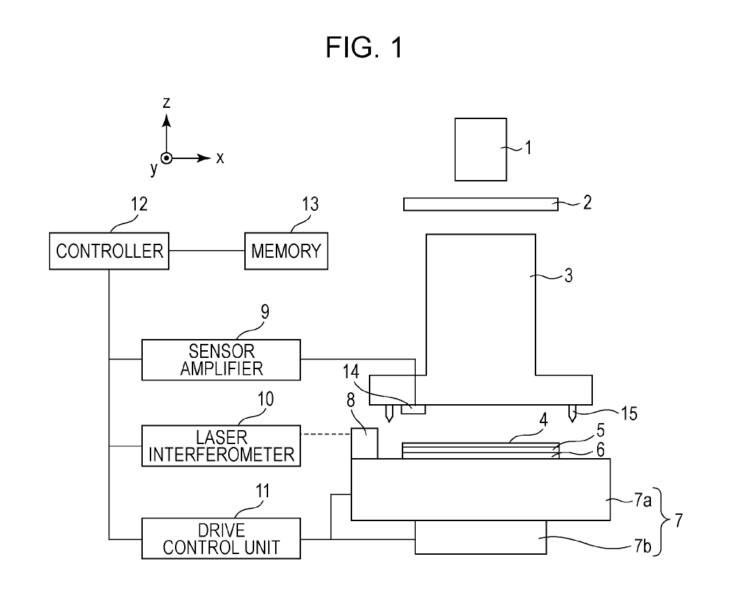

FIG. 1 illustrates a configuration of an optical exposure apparatus (lithography apparatus) according to a first embodiment. An illuminating system 1 includes a non-illustrated light source and is configured to emit light toward a substrate 5. As for the light source, a KrF excimer laser, an ArF excimer laser, or the like may be used. A reticle 2 has a circuit pattern formed thereon, through which part of light emitted from the illuminating system 1 is allowed to pass, and part of light is blocked.

An optical system 3 includes a lens system including a plurality of non-illustrated lenses and a non-illustrated mirror. The lens system is disposed, for example, in a cylindrical housing. The optical system 3 projects a reduced image of the circuit pattern on the surface of an insulating resist 4 coated on the substrate 5 such that light passing though the reticle 2 is focused on the surface of the resist 4.

The substrate 5 is held by a conductive holding part 6 (conductive material) that is grounded. The holding part 6 holds the substrate 5 by using a vacuum chuck configured to hold the substrate 5 by vacuuming air, an electrostatic chuck configured to hold the substrate 5 using an electrostatic force, or the like. As the lithography process proceeds, there is a possibility that an insulating layer such as an insulating layer 21 described below is formed between the substrate 5 and the resist 4. In such a situation, there exists an insulating material on the holding part 6 wherein the insulating material includes the substrate 5, an insulating material thereon such as the insulating resist 4 coated on the substrate 5, the insulating layer 21 provided to prevent a wiring 25 described below from being electrically short-circuited, and the like.

A device control unit 11 controls a moving of a stage 7 under the control of a controller 12 (controller). The stage 7 includes an XY stage 7a configured to be movable together with the holding part 6 and the like in a X-Y plane perpendicular to the optical axis, and a Z stage 7b configured to be movable in a Z-axis direction parallel to the optical axis. On the stage 7, there is also disposed a reflecting mirror 8 in addition to the holding part 6 and the substrate 5 with the resist 4 coated thereon.

The position of the stage 7 is measured by illuminating the reflecting mirror 8 with laser light emitted from a laser interferometer 10. Depending on a difference between a target position of the stage 7 and the measured position, the drive control unit 11 instructs the XY stage 7a and the Z stage 7b to move.

On the other hand, the position of the surface of the target exposure area of the substrate 5 in the Z-axis direction (surface position) is measured using a capacitance sensor 14 (hereinafter, referred to as a sensor 14), which generates an electric field between the sensor 114 and the holding part 6, disposed on a lower end of the optical system 3. By disposing the sensor 14 on the lower end of the optical system 3 as described above, it is possible to reduce the moving distance of the XY stage 7a, which provides a beneficial effect. Alternatively, the sensor 14 may be disposed on a side of the optical system 3.

The method of measuring the surface position using the sensor 14 will be described later in detail. With the apparatus configured in the above-described manner, the adjustment of the position of the substrate 5 is performed such that a desired circuit pattern is transferred to the resist 4. An amplifier 9 is used to apply an AC current to the sensor 14 and measure a voltage (output value).

The controller 12 is connected to the amplifier 9, the laser interferometer 10, and the drive control unit 11, and the controller 12 totally controls the amplifier 9, the laser interferometer 10, and the drive control unit 11. The controller 12 determines a surface position of an insulating material based on an output value of the sensor 14 obtained in a case where the insulating material is located in the electric field and based on information associated with capacitance of the insulating material, and adjusts the surface position of the insulating material at a pattern formation position. The controller 12 stores, in this memory 13, output values from the amplifier 9, the laser interferometer 10, and the drive control unit 11.

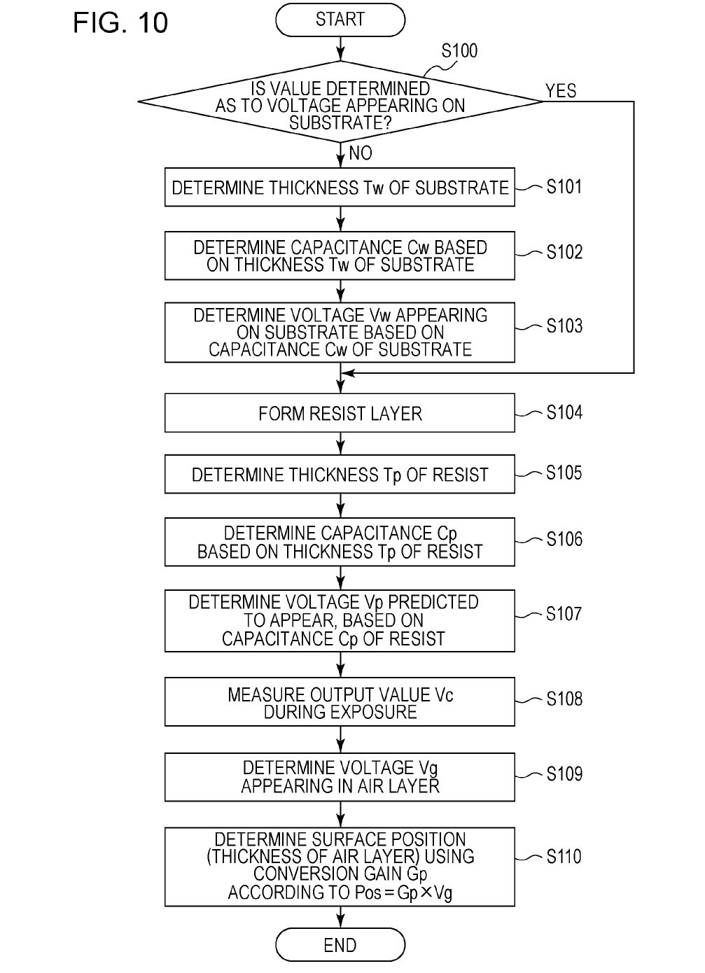

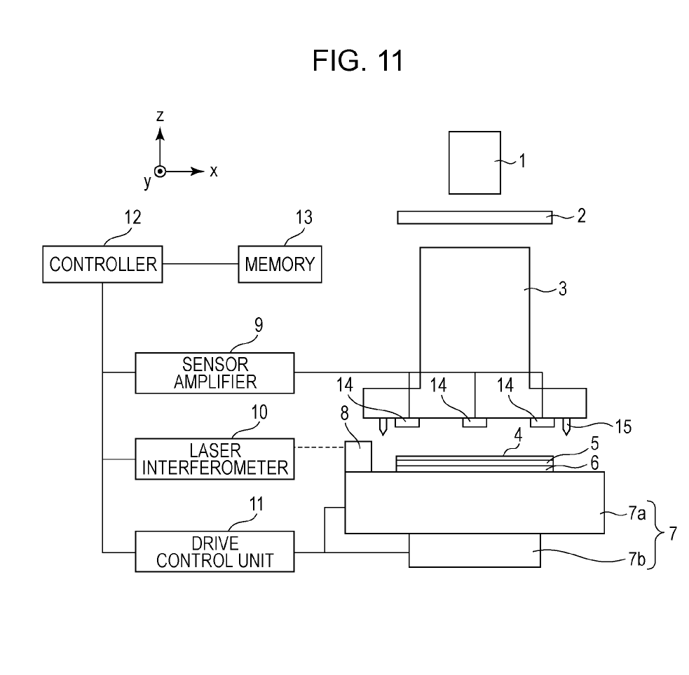

The memory 13 stores a program corresponding to a flow chart illustrated in FIG. 10 described later and other data indicating a dielectric constant ∈w of the substrate 5, a dielectric constant ∈p of the resist 4, a position conversion gain Gp (a proportionality coefficient indicating a relationship between a voltage and a distance, expressed in m/V) associated with the sensor 14, and the like. The memory 13 also stores voltage values appearing on the substrate 5 and the resist 4 obtained as a result of measurement described below, and the like.

A fixing part 15 (fixing unit) is a part that fixes the distance, in a direction in which the electric field is generated, between the holding part 6 and the sensor 14. For example, as illustrated in FIG. 1, the fixing part 15 is disposed on the lower end of the optical system 3. In this case, the Z stage 7b is raised in +Z direction by the drive control unit 11 until the XY stage 7a is brought into contact with the fixing part 15 such that the distance between the optical system 3 and the holding part 6 is fixed thereby making it possible to measure the surface position with high accuracy.

There may be disposed three fixing parts 15. As illustrated in FIG. 1, each fixing part 15 may have a shape with a sharp point such that the fixing part 15 is in contact with the stage 7 with as small a contact area as possible. By using the fixing part 15 with such a shape, it becomes possible to stably fix the surface of the holding part 6.

Alternatively, the fixing part 15 may be disposed on a non-illustrated surface plate on which a supporting part is disposed to support the optical system 3 such that it is allowed to move the Z-stage 7b in −Z direction and fix the position below the Z-stage.

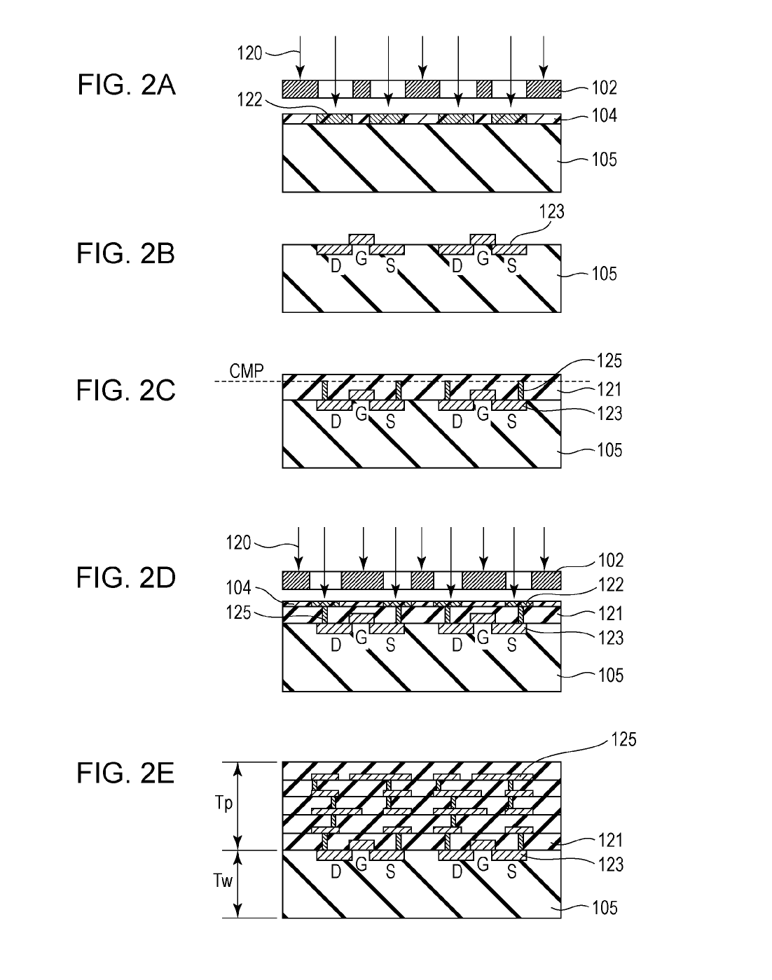

Next, with reference to FIGS. 2A to 2E, a process of forming a circuit pattern on the substrate 105 is described below.

FIG. 2A: FIG. 2A illustrates a state in which the substrate 105 coated with a resist 104 is illuminated with illumination light 120 through a reticle. According to a circuit pattern formed on the reticle, a latent image 122 is formed in areas of the resist 104 illuminated with the illumination light 120. After a step illustrated in FIG. 2A, a sequence of steps of etching, developing, ion doping, and semiconductor forming is performed.

FIG. 2B: By performing the above-described process repeatedly, a structure of a transistor 123 (including a drain (D), a gate (G), and a source (S) is formed as illustrated in FIG. 2B.

FIG. 2C: A wiring layer 125 for connecting the transistor 123 is formed, and an insulating layer 121 is then formed on the wiring layer 125. As for a material for the insulating layer 121, boron phosphorus silicon glass (BPSG), phosphorus silicon glass (PSG), or the like may be used. To form these thin layers in on the transistor 123, a chemical vapor deposition (CVD) technique may be used.

Furthermore, the surface of the insulating layer 121 is polished using chemical mechanical polishing (CMP) powder to planarize the surface to reduce an influence of unevenness of lower layers. The polishing may be performed such that the insulating layer 121 has a thickness of about 0.5 to 1.0 μm.

FIG. 2D: To form a wiring layer 125, a resist 104 is coated on the insulating layer 121 planarized via the CMP polishing process, and a latent image 122 is formed by performing a process similar to that in FIG. 2A.

FIG. 2E: By performing the process of forming the insulating layer 121 in FIG. 2C and the process of forming the wiring layer 125 in FIG. 2D repeatedly ten and more times, a plurality of insulating layers 121 are formed on the first insulating layer 121 such that the resultant insulating layer 121 with a total thickness of Tp is finally formed on the substrate 105.

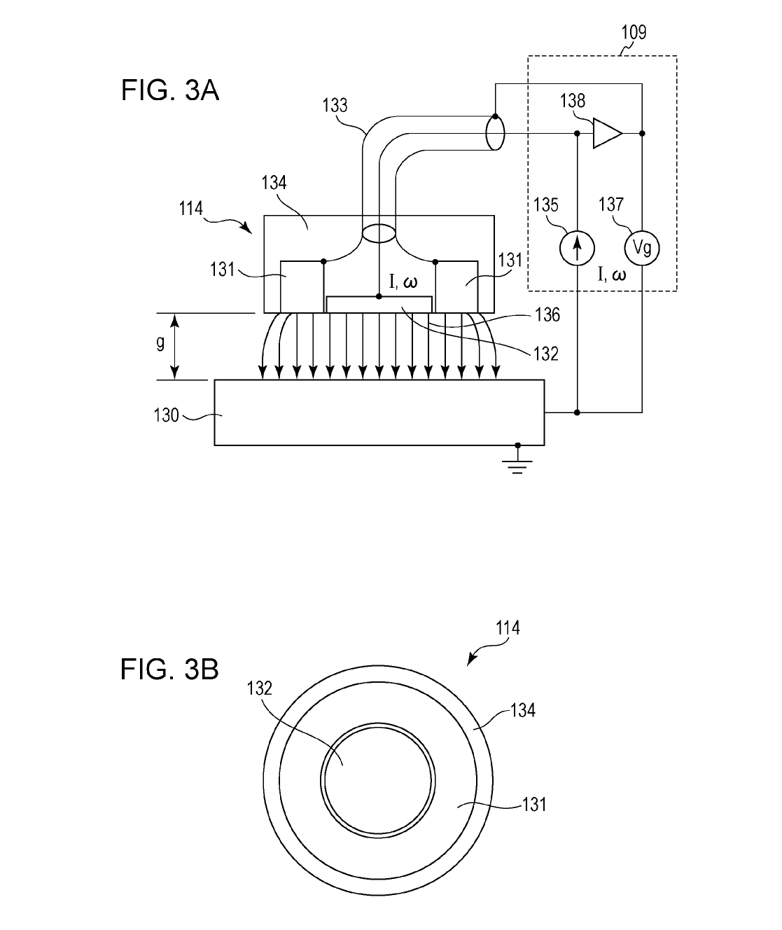

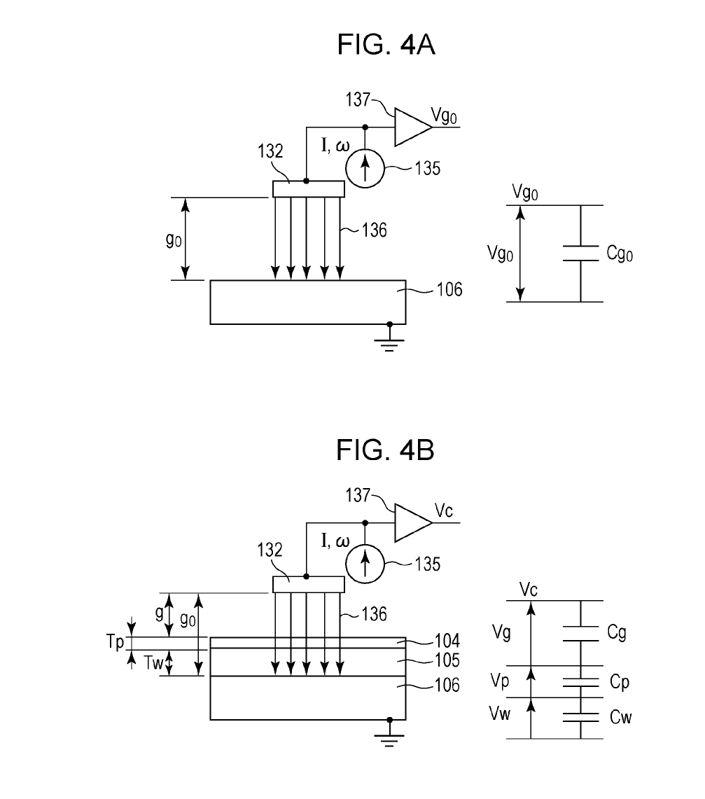

A principle of measuring the capacitance between the sensor 114 and a conductive material or the distance between them by using a capacitance sensor 114 (hereinafter, referred to as a sensor 114) is described below with reference to FIGS. 3A and 3B, and a relationship between a surface position and a value measured by the sensor 114 is described with reference to FIGS. 4A and 4B.

FIG. 3A illustrates a configuration of the sensor 114, a configuration of the amplifier 109, and a conductive material 130 (corresponding to the holding part 6 illustrated in FIG. 1), which are located in the air. FIG. 3B is a view of the sensor 114 seen from the side of the conductive material 130. As illustrated in FIG. 3B, in the surface sensor 114, a surface (sensor surface) on which there are electrodes 131 and 132 has a circular shape. Hereinafter, a space located between the sensor 114 and an object opposing the sensor 114 and filled with air is referred to as an air layer.

The electrode 131 is surrounded by the electrode 132, and the electrode 131 and the electrode 132 are connected to a coaxial cable 133. These parts are molded with a non-conductive epoxy resin 134 into a single piece thereby forming the sensor 114. By providing an AC current using a current source 135, a parallel electric field extending from the electrode 132 to the conductive material 30 is generated as represented by lines of electric forces 136.

A voltage measurement unit 137 detects an AC voltage Vg (output value) via a buffer amplifier 138 with a unity gain where the AC voltage Vg depends on the capacitance C of the space between the electrode 32 and the conductive material 130.

In the state illustrated in FIGS. 3A and 3B, the capacitance C_{g} of the air layer is given by equation (1), and the detected voltage Vg is given by equation (2). From these two equations, it is possible to determine the distance g between the conductive material 130 and the electrode 132. Note that in equations (1) and (2), I denotes a supplied AC current, ω denotes an angular frequency, ∈_{g} de notes a dielectric constant of the air, and A denotes an area of the electrode 132.

$$\begin{matrix}{C}_{g} = \frac{{ɛ}_{g} A}{g} & ( 1 ) \\ \begin{matrix}{V}_{g} = \frac{I}{ω C} \\ = \frac{gI}{ω {ɛ}_{g} A}\end{matrix} & ( 2 )\end{matrix}$$

Next, with reference to FIGS. 4A and 4B, a description is give below as to a situation that may occur in a case where the surface position of the insulating material is measured using the sensor 114. FIG. 4A illustrates a manner in which the position of the conductive holding part 106 is measured using the sensor 114. In a case where an AC current is applied by the current source 135, a parallel electric field is generated in a direction toward the holding part 106 which is a conductor as represented by lines of electric forces 136. Thus, it is allowed for the sensor 114 to detect a voltage Vg₀ corresponding to a capacitance Cg₀ of the air layer between the conductive material 130 and the sensor 14.

On the other hand, FIG. 4B illustrates a state in which, unlike the state illustrated in FIG. 4A, there is a substrate 105 which is an insulator and a resist 104 which is also an insulator on the holding part 6. Also in this case, in a case where an AC current is applied and the surface position of the resist 104 is measured using the sensor 114, a parallel electric field (lines of electric forces 136) is generated in a direction toward the holding part 106 which is a conductor.

In a case where an insulating material such as the resist 104 is inserted between the sensor 114 and the holding part 106 which is a conductor, a voltage Vw is generated on the substrate 105 depending on the capacitance Cw thereof, a voltage Vp is generated on the resist 104 depending on the capacitance Cp thereof, and a voltage Vg is generated on the air layer depending on the capacitance Cg thereof. Therefore, the output value of the sensor 114 is given by the sum of the voltages of the respective layers, that is, Vc=Vw+Vp+Vg.

Therefore, in a case where the distance g₀ to the conductive material 130 is not fixed, the output value Vc of the sensor 114 is variable. However, the voltage on the substrate 105 and the voltage on the resist 104 are unknown, and thus this may produce a situation in which it is difficult to determine the thickness of the air layer, that is, the surface position g.

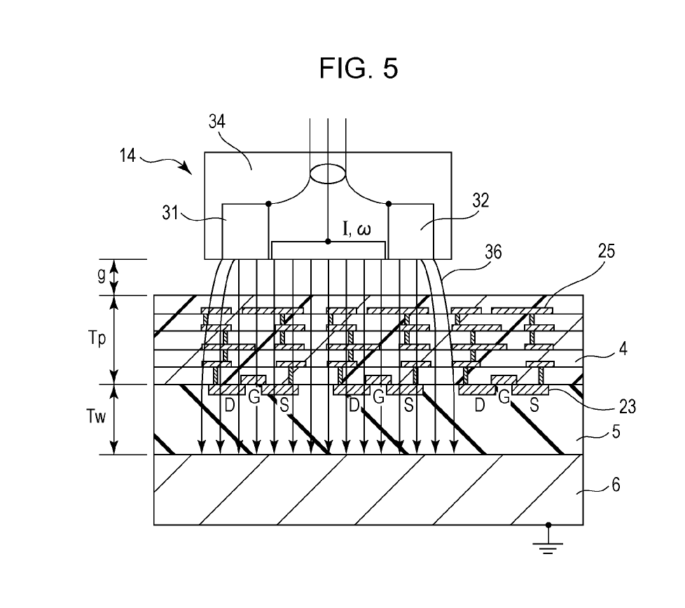

As described below, an optical exposure apparatus according to a first embodiment is capable of measuring the surface position g even for a device having a structure such as that obtained via a plurality of lithography processes such as that illustrated in FIG. 5. The optical exposure apparatus according to the first embodiment is similar in configuration to the optical exposure apparatus illustrated in FIG. 1, which is different from an optical exposure apparatus according to a related technique in that there is no optical detection system for measuring a surface position, but a sensor 14 and a fixing part 15 are provided.

The sensor 14 has a sensor surface that may be 10 to 30 mm in diameter. As illustrated in FIG. 5, in a case where a circuit pattern including a plurality of layers is formed, the density of the wiring layer 25 may high in some areas but low in other areas. The setting the sensor 14 to have a surface diameter to 10 to 30 mm makes it possible to average the influence of the unevenness in density of wiring layer on the measurement error thereby reducing the measurement error. Even in a case where the surface position is measured from a position far from a position optimum for the surface position measurement, the diameter of 10 to 30 mm of the sensor surface makes it possible to reduce the measurement error.

A method of measuring the surface position according to the first embodiment is described below. FIG. 6 to FIG. 9 illustrate an apparatus structure near the sensor 14. FIG. 10 is a flow chart illustrating a surface position measurement process, that is, a content of a program executed by the controller 12 illustrated in FIG. 1 while giving control instructions to the amplifier 9, the laser interferometer 10, the drive control unit 11, and the like. The present embodiment is described below in detail with reference to FIG. 6 to FIG. 10.

In the present embodiment, the optical exposure apparatus executes a process in a premeasurement mode and a process in an exposure mode. In the premeasurement mode, the controller 12 performs a measurement of a first voltage Vg₀ described later and a process in S100 to S107 in the flow chart illustrated in FIG. 10. On the other hand, in the exposure mode, the controller 12 performs a process in S108 to S110 illustrated in FIG. 10.

FIG. 6 illustrates a state in which the stage 7 is not yet brought into contact with the fixing part 15. In FIG. 6, for simplicity, parts of the sensor 14 other than the electrode 32 and peripheral structures other than the fixing part 15 are not illustrated. In this state, the substrate 5 is not yet put on the holding part 6. The XY stage 7a has been moved to an XY position at which to measure the surface position and the XY stage 7a is there at rest under the sensor 14. On the other hand, the Z stage 7b is at rest at an arbitrary position in the Z-axis direction.

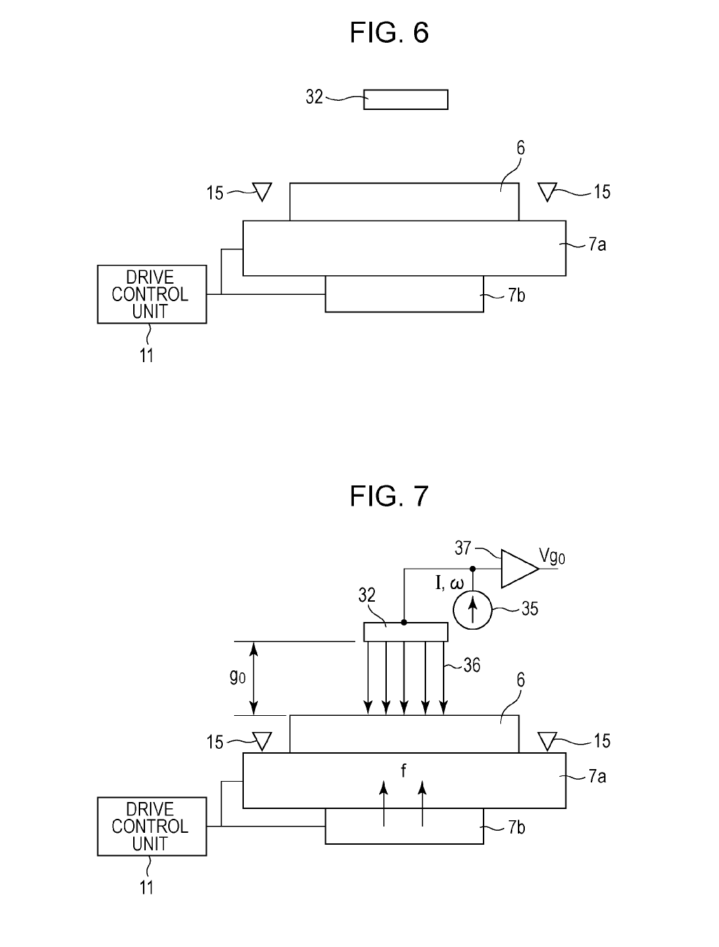

FIG. 7 illustrates a state in which the Z stage 7b has been raised according to an instruction given by the drive control unit 11 until the XY stage 7a has come into contact with fixing part 15. In this situation, to ensure to obtain the same value for the distance g₀ between the electrode 32 and the holding part 6, the force f is to be fixed that is applied by the drive control unit 11 to the holding part 6 in the vertical direction. To achieve this, a current value given as a command signal from the drive control unit 11 is stored in the memory 13, and in a case where the XY stage 7a is brought into contact with the fixing part 15, the force f is controlled at the same value.

In the state in which the XY stage 7a is contact with the fixing part 15 while be urged thereto with the force f, if an AC current is applied from the current source 35, a first voltage Vg₀ (see equation (2)) is detected. The controller 12 stores the current value specified by the drive control unit 11, the distance g₀ between the electrode 32 and the holding part 6 in the state in which the stage 7a is in contact with the fixing part 15 while being urged with the force f, and the first voltage Vg₀ in the memory 13.

The process in the flow chart illustrated in FIG. 10 starts in the state in which the first voltage Vg₀ has been detected. First, the controller 12 determines whether the voltage Vw has been determined which appears across the substrate 5 in the state in which the substrate 5 is put on the holding part 6 (S100). In a case where Vw is not yet determined (the answer to S100 is NO), the controller 12 determines the thickness Tw of the substrate 5. However, in a case where Vw has already been determined (the answer to S100 is YES), the controller 12 performs a process of S104 as described later.

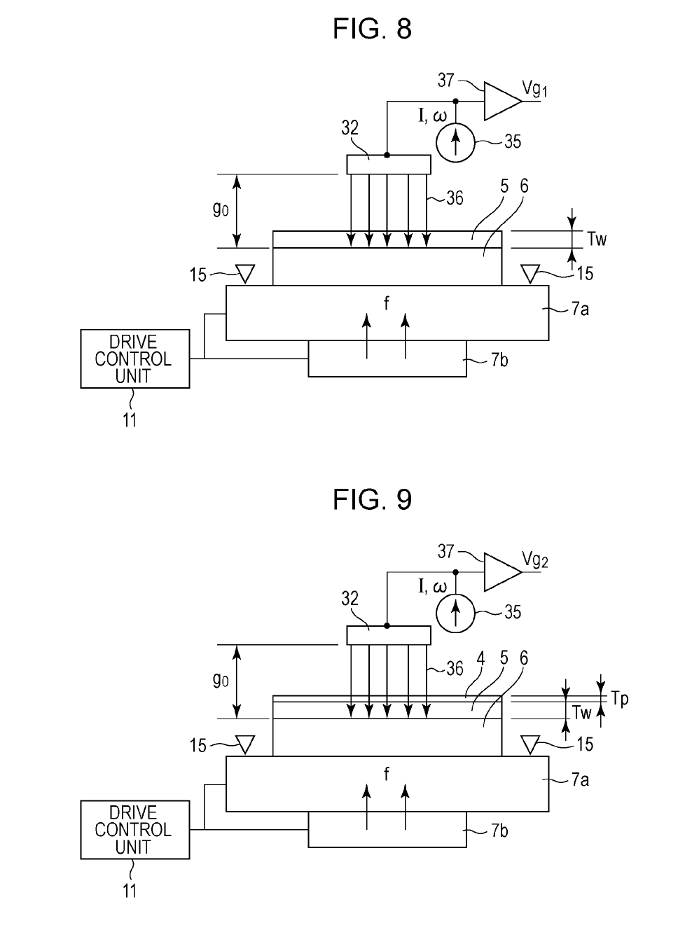

FIG. 8 illustrates a state in which after the substrate 5 is put on the holding part 6, the XY stage 7a is again brought into contact with the fixing part 15 while being urged with the force f in the vertical direction.

In the state illustrated in FIG. 8, an AC current is applied, and a second voltage Vg₁ is detected by the sensor 14. The detected second voltage Vg₁ is the sum of the voltage across the substrate 5 with the thickness of Tw and the voltage across the air layer with the thickness of g₀−Tw. By using equation (2), equation (3) with respect to Vg₁−Vg₀ is obtained. The controller 12 determines the unknown value Tw by solving equation (3). The controller 12 determines a thickness of insulating material using an output value of the sensor 14 obtained in a state in which a distance, in a direction in which the electric field is generated, between the holding part and the capacitance sensor is fixed. Note that the dielectric constant ∈_{w} of the substrate 5 is stored in advance in the memory 13 as a known value.

$${V}_{g 1} - {V}_{g 0} = ( \frac{I}{ω A} ) \{ ( \frac{{g}_{0} - {T}_{w}}{{ɛ}_{g}} + \frac{{T}_{w}}{{ɛ}_{w}} ) - \frac{{g}_{0}}{{ɛ}_{g}} \} = ( \frac{I}{ω A {ɛ}_{g}} ) ( \frac{{ɛ}_{g}}{{ɛ}_{w}} - 1 ) {T}_{w} \qquad ( 3 )$$

Next, using the thickness Tw of the substrate 5 obtained in S101, controller 12 determines the capacitance of the substrate 5 using the equation (4) (S102). Furthermore, the controller 12 determines the voltage Vw across the substrate 5 by calculating equation (5) (S103). The voltage Vw across the substrate 5 is also stored in the memory 13.

$$\begin{matrix}{C}_{w} = \frac{{ɛ}_{w} A}{{T}_{W}} & ( 4 ) \\ {V}_{w} = \frac{I}{ω {C}_{W}} & ( 5 )\end{matrix}$$

Next, the resist 4 is coated on the substrate 5 (S104). FIG. 9 illustrates a state in which after the resist 4 is coated on the substrate 5, the XY stage 7a is again brought into contact with the fixing part 15 while being urged with the force f in the vertical direction.

While maintaining this state, an AC current is again applied, and the sensor 14 detects a third output voltage Vg₂. By using a method similar to that in S101 to S103, the controller 12 calculates the voltage Vp across the resist 4. That is, controller 12 determines the thickness Tp of the resist 4 using equation (6) (S105), the capacitance Cp of the resist 4 using equation (7) (S106), and the voltage Vp across the resist 4 using equation (8) (S107). Note that ∈ₚ denotes the dielectric constant of the resist 4.

$$\begin{matrix}{V}_{g 2} - {V}_{g 1} = ( \frac{I}{ω A {ɛ}_{g}} ) ( \frac{{ɛ}_{g}}{{ɛ}_{p}} - 1 ) {T}_{p} & ( 6 ) \\ {C}_{P} = \frac{{ɛ}_{P} A}{{T}_{P}} & ( 7 ) \\ {V}_{P} = \frac{I}{ω {C}_{P}} & ( 8 )\end{matrix}$$

Next, a process of determining the surface position of the resist 4 during the exposure process is described below. In the exposure process, the stage 7 is to be moved, and thus it is not allowed to use the fixing part 15. Therefore, the distance to the holding part 6 is not equal to g₀ as in FIG. 6 to FIG. 9. Therefore, the surface position is determined as follows. The sensor 14 detects the voltage Vc at each position where to determine the surface position (S108). In this case, the voltage Vc is measured in a state in which the sensor 14 is apart from the surface of the insulating material by a distance. The controller 12 then determines the voltage across the air layer with the thickness g using equation (9) taking into account the voltage Vw across the substrate 5 and the voltage Vp across the resist 4 (S109).

V_{g}=V_{c}−V_{w}−Vₚ (9)

Finally, the controller 12 determines the thickness of the air layer, that is, the surface position g according to equation (10) by calculation, using the voltage V_{g} calculated using (9) and the position conversion gain Gp stored in advance in the memory 13 (S110).

g=GₚV_{g} (10)

The process in S100 to S110 in the flow chart in FIG. 10 has been described above. In the present embodiment, the voltage is measured by the sensor 14 before and after a change occurs in the thickness of the insulating material existing (providing) on the holding part 6. Based on the difference in measured voltage, the voltage across each insulating material in the electric field is determined. Thus, the controller 12 is capable of determining the surface position. That is, the controller 12 determines a thickness of the one of the insulating layers using a difference of output values of the sensor 14 obtained before and after the one of the insulating layers is formed. And then, the controller 12 adjusts the surface position of the insulating material at the pattern formation position using the determined surface position by controlling the device control unit 11. The pattern formation position may be a preferable position considering with an imaging plain of light. Note that the step of calculating the capacitance Cw and Cp (according to equation (4) and equation (7)) may be skipped if equation (2) is used.

As described above, as the process of producing the device proceeds, layers such as insulating layers 21 and wiring layers 25 are formed progressively into the multilayer structure on the substrate 5. In addition, metal oxide layers which are insulators are also formed in the multilayer structure. Each time one insulating layer 21 is formed on the substrate 5 and thus a change in total thickness of the insulating material occurs, the sensor 14 performs the measurement using the fixing part 15.

By performing steps S104 to S110, the controller 12 determines the surface position by determining the voltages across the respective insulating layers 21. In a case where the insulating layers 21 successively formed into the multilayer structure have the same dielectric constant, it is not necessary to determine the voltage across each insulating layer 21, but it is sufficient to properly change the voltage values one of which is subtracted from the other according to equation (6). The controller can determine the thickness of the insulating layer 21 at a time, and to determine the voltage across each of the insulating layers 21 at a time.

Although the surface position may be determined based on a measurement value given by the sensor 14 for one point in an area of the substrate 5, using measurement values at least at three points which do not lie in a line makes it possible to measure the degree of the slope of the surface of the substrate 5. Furthermore, after data of surface positions at a plurality of points is determined based on measurement values at representative points such as three points which do not lie in a line, it is possible to surface positions at points different from the representative points by performing data interpolation.

In a case where a pattern of circuits or the like is formed in a plurality of shot areas on the substrate 5, the sensor 14 measures the surface positions at least in two shot areas. The controller 12 determines a surface position in each of at least two shot areas using an output value of the sensor 14 obtained in a state in which the insulating material is located in the electric field and information associated with the capacitance of the insulating material. It may be more preferable to perform the measurement using the sensor 14 in a larger number of shot areas, for example, all shot areas. This makes it possible to obtain a map of surface positions of the substrate 5 taking into account small unevenness of the surface of the substrate 5 and nonuniformity of the thickness of the resist 4. Thus controller 12 more accurately adjusts the pattern formation position with respect to the surface of the target exposure area. In a case where the surface position measurement of the resist surface using the sensor 14 is performed for each shot area, information associated with the capacitance is determined for each shot area in terms of the thickness of the insulating material including the substrate, the resist, and the like, the capacitance of the insulating material determined from the thickness thereof, the voltage across the insulating material, and the like. That is, a thickness map of the insulating material is to be determined, a capacitance map, or a voltage map, or the like, of the plurality of shot areas on the substrate, using the method according to the embodiment described above.

Furthermore, in the present embodiment, the voltage across the air layer is determined taking into account the voltages across the substrate 5 and the resist 4, which are both insulating material, and thus the present embodiment provides a benefit that it is possible to perform the surface position measurement even during the exposure process. That is, it is possible to determine the surface position even in a case where the distance between the sensor 14 and the holding part 6 may be changed, which may occur in a case where the fixing part 15 is not used or which may occur due to a thermal deformation or the like of the substrate 5, and even in a state in which the sensor 14 is apart from the insulating material by a distance. This may be advantageous compared with a case in which the thickness of the substrate 5 or the thickness of the resist 4 is simply subtracted from the initially measured distance g₀ between the sensor 14 and the holding part 6.

In the present embodiment, even in a case where only the sensor 14 is used as a measurement device for measuring the surface position, it is possible to accurately measure the surface position of the substrate 15. The unnecessary of an oblique incidence optical detection system allows it to reduce the installation space for the peripheral devices near the optical system, which allows a reduction in cost.

A lithography apparatus according to a second embodiment is described below. In the second embodiment, the lithography apparatus has a similar configuration to that according to the first embodiment except that the position conversion gain Gp is not stored in the memory, and thus a further description of the configuration is omitted. A method of measuring a surface position according to the second embodiment is described below with reference to equations described above.

Each time the substrate 5 or the resist 4 is put on the holding part 6, the sensor 14 performs the measurement using the fixing part 15. Also in this second embodiment, as in the first embodiment, the capacitance Cw and Cp of the respective insulating materials are determined according to equation (4) using the thicknesses of Tw and the Tp of the respective insulating materials.

Next, during the exposure process, the sensor 14 measures the voltage Vc without using the fixing part 15. From this voltage Vc, the sum Cc of the capacitance of the insulating material and the capacitance of the air layer, exiting between the holding part 6 and the sensor 14, is determined according to equation (2). Thus, the obtained capacitance Cc and the capacitance Cg of the air layer have a relationship represented by equation (11).

$$\frac{1}{{C}_{C}} = \frac{1}{{C}_{W}} + \frac{1}{{C}_{p}} + \frac{1}{{C}_{g}} \qquad ( 11 )$$

According to equation (11), the reciprocal of the capacitance Cg of the air layer is obtained by subtracting the reciprocal of the capacitance Cw of the substrate 5 and the reciprocal of the capacitance Cp of the resist 4 from the reciprocal of the capacitance Cc obtained from the voltage Vc measured in the state in which the distance between the holding part 6 and the sensor 14 is at any value. The capacitance Cg of the air layer obtained in this manner has a relationship according to equation (1) with the thickness of the air layer, that is, with the surface position g. Therefore, based on the information associated with the capacitance Cg of the air layer, it is also possible to determine the surface position g of the surface of the insulating material.

Furthermore, in the present embodiment, as with the first embodiment, in a case where an insulating layer 21 other than the resist 4 is formed on the top of the multilayer structure, it is possible to determine the surface position g as measured as the distance to the insulating material by using output values of the sensor 14 measured while using the fixing part 15 before and after the thickness of the insulating material changes.

Therefore, from the output value of the sensor 14 obtained for an arbitrary distance between the holding part 6 and the sensor 14, it is also possible to determine the surface position g using the capacitance of the insulating material.

### Third Embodiment

FIG. 11 illustrates a configuration of an optical exposure apparatus according to a third embodiment. The third embodiment is different from the first embodiment in that three sensors 14 are disposed on the side of a housing in which the optical system 3 is placed, and the position conversion gain Gp of each sensor 14 is stored in the memory 13.

Also in a case where the surface position of the insulating layer 4 is measured using a plurality of sensors 14, each sensor measures the surface position according to the flow chart illustrated in FIG. 10. Use of the plurality of sensors 14 allows a reduction in the total time used to measure voltages over the whole area of the insulating layer 4. In a case where the measurement is performed in the same given period of time, it is possible to perform measurement a plurality of time for the same position and achieve a more accurate measurement by determining the average of a plurality of measured values.

### Fourth Embodiment

In the first to third embodiments, it is assumed that the lithography apparatus is an optical exposure apparatus. In a fourth embodiment, a discussion is given below for a case where the lithography apparatus is an electron beam lithography exposure apparatus (not shown). The structure of the electron beam lithography exposure apparatus is similar to that of the exposure apparatus illustrated in FIG. 1 except for some differences. One of differences is that the reticle 2 is not used.

Furthermore, the optical system 3 is replaced with an electron optical system including an electrostatic lens and/or an electromagnetic lens. Using these lenses, an electron beam is focused on the surface of a target object such that a latent image 22 of a circuit pattern is directly formed in the resist 4. As with the first to third embodiments, the sensor 14 and the fixing part 15 are provided. The electron beam lithography exposure apparatus according to the present embodiment also operates in two operation modes. However, instead of the light exposure mode, an electron exposure mode is performed.

In the present embodiment, it is possible to measure the surface position using the sensor 14, which is a small measurement device, without using other surface position measurement devices, which allows the present embodiment to be applied to an apparatus in which the target object to be exposed is located close to the housing in which the optical system is disposed as in the electron beam lithography exposure apparatus.

In the electron beam lithography exposure apparatus, unlike the first to third embodiment, writing of a circuit pattern is performed in a vacuum environment, and thus the dielectric constant stored in the memory 13 is not for the dielectric constant ∈g of the air but for the dielectric constant ∈₀ of the vacuum, and the position conversion gain Gp in the vacuum is stored in the memory 13.

In the electron beam lithography exposure apparatus according to the fourth embodiment, the surface position may be measured using a similar method to those according to the first to third embodiments, and thus a further description thereof is omitted.

The present invention has been described above with reference to the first to fourth embodiments. In the first to fourth embodiments, as described above, the controller 12 determines the surface position of the insulating material based on the information associated with the capacitance and the output value of the sensor 14 in the state in which the surface of the insulating material is at an arbitrary position. Examples of the information associated with the capacitance are the thickness of the insulating material, the capacitance of the insulating material, and the voltage across the insulating material. Each embodiment provides a benefit that it is allowed to perform the measurement using only one measurement device.

Note that the arbitrary distance between the surface of the insulating material and the sensor 14 means that the distance between the surface of the insulating material and the sensor 14 has an arbitrary value within a range in which the specifications of the sensor 14 allow it to achieve desired measurement accuracy.

In addition to the first to fourth embodiments described above, other embodiments are possible. Some examples are described below.

In a case where it is allowed to get information about the thickness of the substrate 5 in advance because the substrate 5 is standardized material, the voltage Vw across the substrate 5 may be directly calculated without performing the process (S101) of calculating the thickness Tw according to equation (3). In the embodiments described above, it is assumed by way of example that the surface position is measured while performing the exposure process on the resist 4. Alternatively, the surface position of the substrate 5 may be measured in advance over the entire area of the substrate 5.

Still alternatively, thickness information of the substrate 5, the resist 4, and the insulating layer 21 may be acquired in advance from an external apparatus such as a film thickness measurement device. In this case, it is allowed to reduce the time spent by the lithography apparatus to measure the thickness, which provides a benefit that an increase in throughput is achieved.

As for the surface position information which is obtained each time a new insulating layer (one of insulating layers) is formed on the substrate 5 in the premeasurement mode or the exposure mode, the surface position obtained for one substrate 5 may be applied to other substrates in the same production lot in a case where in the production process such as the exposure, the multilayer film formation, the polishing, and the like, no significant error occurs among substrates in the same lot. This results in a reduction in the number of times that the measurement using the sensor 14 is performed, and thus it is possible to increase the throughput.

In the description of the method of measuring the surface position according to the respective embodiments, it is assumed by way of example that the surface position is measured in the optical exposure apparatus or the electron beam lithography exposure apparatus. Alternatively, the method according to one of the embodiments may be applied to other measurement devices in which the distance from a certain position to a surface of an insulating material on a conductor is measured as a surface position. Depending on the accuracy necessary in measuring the surface position, a voltage across a thin film layer such as a resist or capacitance thereof may be neglected.

A method of producing a device according to an embodiment of the invention includes forming a pattern on a substrate while determining a surface position using a lithography apparatus according to one of the embodiments described above or a lithography apparatus using an imprinting technique, and etching the substrate having the pattern formed thereon. The method may further include a process (such as developing, oxidation, film formation, evaporation, doping, planarization, resist removal, bonding, packaging, and/or the like).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-201377, filed Sep. 27, 2013, which is hereby incorporated by reference herein in its entirety.

What is claimed is:

1. An apparatus comprising:
a holding part being conductive and configured to hold an insulating material;
a capacitance sensor configured to generate an electric field between the capacitance sensor and the holding part; and
a controller configured to determine a surface position of the insulating material based on an output value of the capacitance sensor obtained in a case where the insulating material is located in the electric field and based on information associated with capacitance of the insulating material, and to adjust the surface position of the insulating material at a pattern formation position using the determined surface position.

2. The apparatus according to claim 1, wherein the controller is configured to determine a thickness of the insulating material using an output value of the capacitance sensor obtained in a state in which a distance, in a direction in which the electric field is generated, between the holding part and the capacitance sensor is fixed, and to determine the information associated with the capacitance of the insulating material based on the thickness.

3. The apparatus according to claim 2,
wherein the insulating material includes a plurality of insulating layers formed one on another in a multilayer structure, and
wherein in a case where one of the insulating layers is formed, the controller is configured to determine a thickness of the one of the insulating layers using output values of the capacitance sensor obtained before and after the one of the insulating layers is formed.

4. The apparatus according to claim 3, wherein the controller is configured to determine the thickness of the one of the insulating layers using a difference of output values of the capacitance sensor obtained before and after the one of the insulating layers is formed.

5. The apparatus according to claim 1, wherein the information associated with the capacitance of the insulating material is one of information indicating the capacitance of the insulating material and information indicating a voltage generated the insulating material corresponding to the electric field.

6. The apparatus according to claim 1, wherein the controller is configured to determine the surface position of the insulating material based on a difference between a voltage generated across the insulating material and the voltage measured in a state in which the capacitance sensor is apart from the surface of the insulating material by a distance in a case where the output value is a voltage.

7. The apparatus according to claim 1, wherein the controller is configured to determine the surface position of the insulating material based on a difference between the reciprocal of the capacitance of the insulating material and the reciprocal of the capacitance value obtained by the voltage measured in a state in which the capacitance sensor is apart from the surface of the insulating material by a distance in a case where the output value is a capacitance.

8. The apparatus according to claim 1, in a case where a pattern is formed in a plurality of shot areas on a substrate, the controller is configured to determine a surface position in each of at least two shot areas using an output value of the capacitance sensor obtained in a state in which the insulating material is located in the electric field and using the information associated with the capacitance of the insulating material.

9. A method of measuring a surface position, comprising:
providing an insulating material on a conductive material;
obtaining information associated with capacitance of the insulating material;
obtaining an output value of a capacitance sensor in a state in which the insulating material is located between the conductive material and the capacitance sensor; and
determining the surface position of the insulating material based on the information associated with capacitance of the insulating material and the output value of the capacitance sensor.

10. The method according to claim 9, wherein obtaining the information associated with the capacitance of the insulating material includes
determining a thickness of the insulating material using an output value of the capacitance sensor obtained in a state in which a distance between the conductive material and the capacitance sensor in a direction in which the electric field is generated is fixed at a predetermined value, and
obtaining the information associated with the capacitance of the insulating material based on the determined thickness.

11. The method according to claim 9, wherein the obtaining the information associated with the capacitance of the insulating material includes obtaining information associated with the capacitance of the insulating material based on a thickness of the insulating material measured using a film thickness measuring device.

12. The method according to claim 9, wherein the obtaining the information associated with the capacitance of the insulating material is performed each time the providing the insulating material on the conductive material is performed.

13. An apparatus configured to measure a surface position of an insulating material on a conductive material, comprising:
a capacitance sensor; and
a controller configured to determine the surface position of the insulating material based on information associated with capacitance of the insulating material and an output value of the capacitance sensor obtained in a state in which the insulating material is located between the conductive material and the capacitance sensor.

14. A method of producing a device, comprising:
forming a pattern on a substrate using an apparatus; and
performing an etching process on the substrate on which the pattern is formed,
wherein the apparatus includes
a holding part being conductive and configured to hold an insulating material,
a capacitance sensor configured to generate an electric field between the capacitance sensor and the holding part, and
a controller configured to determine a surface position of the insulating material based on an output value of the capacitance sensor obtained in a case where the insulating material is located in the electric field and based on information associated with capacitance of the insulating material, and to adjust the surface position of the insulating material at a pattern formation position using the determined surface position.
